(19) United States
(12) Patent Application Publication
(10) Pub. No.: US 2010/0141270 A1
(43) Pub. Date: Jun. 10, 2010

(54) PROCESS AND DEVICE TO MEASURE AT LEAST ONE QUALITATIVE VALUE OF A FIBROUS WEB

(76) Inventors: Oliver Kaufmann, Heidenheim (DE); Rudolf Münch, Konigsbronn (DE); Helena Johnansson, Wurzburg (DE); Jens Haag, Heidenheim (DE); Thomas Ischdonat, Bachhagel (DE); Susanne Moses, Augsburg (DE)

Correspondence Address: TAYLOR & AUST, P.C., P.O. Box 560, 142. S Main Street, Avilla, IN, 46710, US

(21) Appl. No.: 12/629,178

(22) Filed: Dec. 2, 2009

Related U.S. Application Data
(63) Continuation of application No. PCT/EP2008/054282, filed on Apr. 9, 2008.

(30) Foreign Application Priority Data
Jun. 2, 2007 (DE) 10 2007 025 815.3

(51) Int. Cl. G01R 27/04

(52) U.S. Cl. 324/634

(57) ABSTRACT

A process to measure at least one qualitative measure of a moving fibrous web. The fibrous web being a web of paper or cardboard. The process including the steps of influencing, evaluating and determining. The influencing step includes the influencing of at least one microwave resonator by the fibrous web. The evaluating step including the evaluating of at least one resonance curve of the at least one microwave resonator. The determining step including the determining of at least one quality measure of the fibrous web dependent upon results of the evaluating step.

### CROSS REFERENCE TO RELATED APPLICATIONS

This is a continuation of PCT application No. PCT/EP2008/054282, entitled “PROCESS AND DEVICE TO MEASURE AT LEAST ONE QUALITATIVE VALUE, E.G. THE MOISTURE CONTENT OR THE BASIS WEIGHT, OF A WEB OF FABRIC, IN PARTICULAR A WEB OF PAPER, BY GAUGING THE RESONANCE FREQUENCY AND THE LINE WIDTH THROUGH A MICROWAVE RESONATOR THAT RESPONDS TO THE WEB OF FABRIC, E.G. A PLANAR RING RESONATOR”, filed Apr. 9, 2008, which is incorporated herein by reference.

### BACKGROUND OF THE INVENTION

1. Field of the Invention

The invention pertains to an apparatus and a process to measure at least one qualitative measure of a moving web of fibrous material, in particular, webs of paper or cardboard. The invention pertains furthermore to a corresponding measuring device.

2. Description of the Related Art

Measurements of qualitative values of paper, such as for example, the basis weight GSM (grams/m²), the moisture content, the content of filler or the composition of the filler material, respectively, are in the paper industry conventionally conducted in terms of traversing measuring units. A significant part of this process of measuring is applied to only a very small portion of the web of paper since this web moves at a speed of up to 2,000 m/min past the measuring device while the measurement device moves transversely to the direction of movement of the web of paper.

In contrast to those conventionally conducted measuring procedures, the so called Spectrafoil Measuring System extends across the entire width of the web of material providing simultaneous measurements over the entire width of the web of paper. The measuring elements consist of electrodes which are embedded in ceramic and which are placed under a sieve. In that context the electrical conductivity of paper or its dielectric properties, respectively, is measured. There is a linear correlation between the electrical conductivity of paper and its water weight, so this measuring system establishes the moisture content of the paper. But this method has the inherent disadvantage that the electrical conductivity of the mixture of water and paper varies considerably with the composition of its ingredients, such that unambiguous measurements are very difficult. Additionally such measuring systems are limited to those sections of the paper machine where the paper contains a very high level of moisture such as in the forming segment of the machine.

In a procedure to determine the water weight within a forming segment, known from EP-A-1 624 298, microwaves are produced inside the fibrous suspension by microwave resonators and the speed of the propagating waves is measured.

What is needed in the art is a measurement system capable of use in various stages of paper manufacture, regardless of moisture content.

### SUMMARY OF THE INVENTION

An objective of the present invention is to produce reliable measurements in various stages of the manufacturing process as well as various locations of the paper making machine, respectively, that means to make measurements in areas where the web of fibrous material is very moist as well as in areas where the process is completed and where the fibrous material has been air dried. In case of webs of paper or cardboard it should be possible to make measurements of the utmost reliability in various locations of the paper machine as well as various stages of the process, such as for example, in the forming segment where the paper is still very moist up to the stage where the process is almost completed and the paper has been air dried where, for example, the paper is being loaded onto a roller.

The task according to the present invention is accomplished by using a method to determine at least one measure of quality of moving webs of fibrous material, in particular, of webs of paper or of cardboard. Resonance curves from at least one microwave resonator that has been affected by the webs of fibrous material as they passed through them are evaluated, and the evaluation of this resonance curve is used to determine the respective measure of the quality of the web of material.

The preferred way to determine the respective measures of quality consists of determining the position of the resonance frequency along the frequency axis as well as the shape and width of the resonance curve.

It is of advantage if, for a particular measure of quality intended to be determined, a specific primary frequency is coupled into the microwave resonator. In this context several different measures of quality can be determined by coupling the associated specific primary frequencies into the microwave resonator.

According one embodiment of the present invention at least one of the primary frequencies coupled into the microwave resonator is calibrated to determining the moisture content of the web of fibrous material.

In order to determine the moisture content it is advantageous if a microwave resonator, which is capable of operating in the range of frequencies between 1 GHz up to about 25 GHz is set to operate in the regime around 2.4 GHz and in particular in the regime around 22 GHz.

It is of further advantage if at least one of the primary frequencies coupled into the microwave resonator is associated with determining the basis weight of the web of fibrous material. In this context it is very opportune if the primary frequency value of the microwave resonator, which is calibrated to measure the basis weight, is in a regime where the dielectric constants for all of the expected ingredients contained in the web of fibrous material are, for the most part, the same. This ensures that the entire web of fibrous material can be considered as a uniform measurement domain.

It is preferred that for the purpose of determining the basis weight that the microwave resonator operates in the general range of 22 GHz up to about 100,000 GHz, in particular in the range of 50 GHz up to about 500 GHz, and preferably in the range of 60 GHz up to about 300 GHz.

It is of further advantage if in addition one of the primary frequencies coupled into the microwave resonator is calibrated to determining at least one of the filler materials contained in the web of fibrous material. It is therefore possible to determine various filler materials which are contained in the web of fibrous material. By combining a plurality of selective measurements it is furthermore possible to improve the accuracy of the measurements. According to a particular convenient version of the process proposed by this invention it is possible, by appropriate selection of the primary frequencies, to measure both the content of the intended filler ingredients and the moisture content and then to determine the basis weight from a combination of these selective measurements.

It is preferred that the measurements of the qualitative measures of the moving webs of fibrous material are conducted by several stationary microwave resonators that are distributed across the width of the moving web of material. In this context it is advantageous if the majority of the microwave resonators, which are distributed across the width of the moving web of fibrous material, are determining at least one common measure of quality simultaneously. Alternatively or in addition to, measurements of this quality parameter are conducted by at least one microwave resonator that traverses across the width of the moving web of fibrous material.

Since this procedure is based on microwave technology, the sensor elements, in this case the microwave, resonators can be made sufficiently small to conduct measurements without traversing across the width of the web of material. Furthermore, commercially available microwave elements cover a wide range of frequencies, which allows for them to be separated into a variety of material properties as well as a wide range of qualitative values and to measure them independently from one another since they differ significantly in the frequency regimes.

The basic concept of these measurements is preferably based on evaluating the resonance curves of the different microwave resonators. In this context the present invention makes use of the circumstance that the relative position of the resonance frequency on the frequency axis, i.e. its value, as well as the width of the resonance curve are both determined by the design of the microwave resonator and by the material with which this resonator interacts. By appropriate selection of the primary frequencies that are coupled with the microwave resonator it is possible to measure different properties of the web of fibrous material or properties of the paper, respectively.

The significant value for these sorts of measurements is the dielectric constant of the material that is being investigated and with which the resonator interacts. The dielectric constant determines the frequency behavior and the dampening behavior of the material. Due to the interactions of different materials with which the resonator interacts, there is a resulting shift of the resonance frequency as well as a change in the width of the resonance curve. A larger dielectric constant produces a shift of the resonance frequency to a lower value while the width of the resonance curve increases.

For frequencies around 2.4 GHz and at temperatures around, for example 20° C., the relative dielectric constant of water is 80 while the relative dielectric constant of fibers is only around 3. This means that in this particular regime of frequencies water is the component that can be selectively measured.

In contrast to this, measurements of the basis weight GSM require a primary frequency in a regime in which all the ingredients contained in the web of fibrous material have dielectric constants that are, for the most part, the same. This ensures that the web of fibrous material or paper can be regarded as a uniform domain. The measuring range to achieve this is in the frequency regime of >20 GHz and in particular in the frequency regime of >100 GHz.

In the same manner frequency regimes can be found in which the filler materials that are contained in the web of fibrous material or in paper, respectively, can be selectively measured. Furthermore by combining measurements of the aforementioned selective methods more precise measurement accuracies can be achieved.

According to the present invention the initially stated objective is achieved through a device to determine at least one measure of quality of a moving web of fibrous material, in particular, webs of paper or webs of cardboard, which includes at least one microwave resonator, which furthermore includes devices to evaluate details of the resonance curve of the microwave resonator, which was influenced by the web of fibrous material, and which includes devices to determine the relevant measures of quality from the evaluation of the resonance curves.

In this context several stationary microwave resonators are distributed across the width of the moving web of fibrous material. Alternatively or in addition to this, at least one microwave resonator is employed that traverses the width of the web of material transversely to the direction of movement of the web in the machine.

Preferably at least one microwave resonator is employed to determine the basis weight and at least one other resonator is employed to determine the moisture content.

According to one preferred convenient version of the device proposed by the present invention at least one microwave resonator includes a planar microwave ring resonator. In this context the size of the planar microwave ring resonator can be as small as on the order of size of the wavelength of the primary radiation.

The individual microwave resonators or planar microwave ring resonators, respectively, can be embedded into a ceramic, and positioned in a press or in the press nip. In this way the distance between the sensor elements or the microwave resonators and the web of fibrous material can be kept constant.

It is of further advantage if microwave resonators are employed for determining different measures of quality and if devices and/or algorithms are incorporated to quantify from these measurements a governing value that is used in the manufacture of the web of fibrous material. In this context it is possible, for example, to determine the weight of oven dried paper, which results from the subtraction of the moisture content from the basis weight. To achieve this requires at least one microwave resonator to measure the basis weight and at least one microwave resonator to measure the moisture content.

Through combined arrangements of microwave resonators for measuring different measures of quality it is possible to derive separate dependent quality values. It is along these lines possible to account for the impact of moisture on the measurements of the basis weight or to eliminate the impact.

The device proposed by the present invention can furthermore also be part of an overarching measuring system developed to measure the transverse profile of the basis weight and/or the transverse profile of the moisture content and/or the longitudinal profile of the basis weight and/or the longitudinal profile of the moisture content of a web of fibrous material, in particular, of a web of paper or a web of cardboard.

The positions of the microwave resonators are distributed either along the direction of movement or transverse to the direction of movement of the manufacturing machine, in particular, of a paper or a cardboard machine. It is also possible to integrate at least one microwave resonator into this manufacturing machine such that it can traverse the fibrous web, whose movements can be monitored and recorded, and whose recorded signals can be accordingly accounted for in their evaluation.

Furthermore the microwave resonators can be selected with different natures, differing in nature regarding to resonators and/or regarding the microwave emitters.

An individual microwave resonator can, be located with an air cushion close to the web of paper, while making only very limited contact with the web of paper. It can be, moreover, inserted into a machine component of the manufacturing machine, which contacts the web of fibrous material. In this context the microwave resonator can simultaneously touch both the web of fibrous material and a circulating band, such as, a forming sieve, a compression felt or a drying sieve.

The microwave resonator can be positioned on one side of the web of fibrous material with a metallic reflector on the other side. The metallic reflector might be a metallic rail or a roller or a defined electrical insulator, such as, a solid or a hollow body.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 is a diagram depicting resonance curves resulting from an embodiment of the present invention including one microwave resonator interacting with two different materials; and

FIG. 2 is a schematic top view of a planar microwave ring resonator used to produce the curves of FIG. 1.

Corresponding reference characters indicate corresponding parts throughout the several views. The exemplification set out herein illustrates one embodiment of the invention, in one form, and such exemplification is not to be construed as limiting the scope of the invention in any manner.

### DETAILED DESCRIPTION OF THE INVENTION

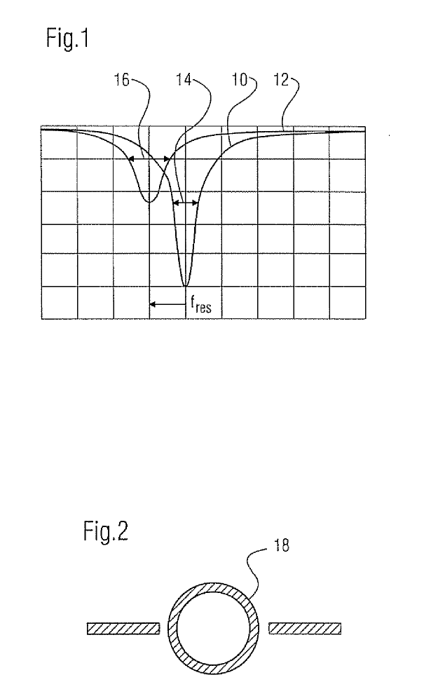

Referring now to the drawings, and more particularly to FIG. 1, there is a diagram depicting two resonance curves 10 and 12 resulting from a microwave resonator, which is interacting with two different materials. The x-axis denotes frequency and the y-axis denotes the amplitude. The minima for each of the resonance curves 10 and 12 occur at the respective resonance frequency fᵣₑₛ. The symbols “14” and “16” denote the respective widths of these resonance curves.

FIG. 1 illustrates how different materials or different conditions of the web of fibrous material, with which the microwave resonator interacts, produce a shift in the resonance frequency fᵣₑₛ as well as a change to the width of the resonance curve. A larger dielectric constant produces a shift of the resonance frequency to a smaller value, while the width of the resonance curve increases as depicted by the two resonance curves 10 and 12.

It is of advantage if at least one of the microwave resonators employed in a machine is a microwave ring resonator. In certain instances it is also conceivable that all of the microwave resonators in a machine are such microwave ring resonators.

In FIG. 2 there is shown a schematic top view of a planar microwave ring resonator 18. This variation of the measuring device, in particular, using a planar microwave ring resonator as a microwave resonator, provides the advantage that the measuring unit can be designed both very compact and very small.

The overall extent of the microwave ring resonator can be at about the scale of size of the wavelength of the primary radiation. So a frequency or resonance frequency, of 100 GHz corresponds to a resonator extent of 3 mm.

Planar microwave ring resonators 18 of this sort can be arranged parallel to one another across the entire width of the machine in order to provide simultaneous measurements recorded without traversing the web, of at least one measure of quality of the web of fibrous material or measure of quality of paper, respectively. In addition or alternatively to this, it is conceivable to employ at least one microwave resonator 18 that traverses the width of the web of fibrous material.

The individual microwave resonators 18 can be embedded, for example, into a ceramic, into a roller or into the nip of a press. One advantage of such a configuration consists of keeping a constant distance between each of the respective sensor elements or resonators, respectively, or between the resonator and the web of fibrous material.

It is furthermore conceivable to utilize other combinations of sensors in order to determine governing values relating to, for example, the weight of oven dried paper (=basis weight−moisture content). In this instance it is conceivable to employ at least one microwave ring resonator 18 to determine the basis weight as well as at least one microwave ring resonator 18 to determine the moisture content. Such arrangements can, furthermore, be used to derive separate dependent quality values. It is, for example, possible to determine the impact of moisture on the measurements of the basis weight or to eliminate its effect on it.

While this invention has been described with respect to at least one embodiment, the present invention can be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

### LIST OF REFERENCE SYMBOLS

10 resonance curve
12 resonance curve
14 width
16 width
18 microwave resonator, microwave ring resonator
fᵣₑₛ resonance frequency

What is claimed is:

1. A process to measure at least one qualitative measure of a moving fibrous web, the fibrous web being one of a web of paper and cardboard, the process comprising the steps of:
influencing at least one microwave resonator by the fibrous web;
evaluating at least one resonance curve of said at least one microwave resonator; and
determining at least one quality measure of the fibrous web dependent upon results of said evaluating step.

2. The process of claim 1, wherein said determining step includes the steps of:
determining a position of resonance on a frequency axis of said resonance curve; and
determining at least one of a shape and a width of said resonance curve in order to establish said quality measure.

3. The process of claim 2, wherein said determining at least one quality measure step includes the steps of:
calibrating at least one primary frequency to at least one selected measure of quality; and
coupling said at least one primary frequency to said microwave resonator to determine said at least one selected measure of quality.

4. The process of claim 3, wherein said at least one primary frequency is a plurality of different primary frequencies, said at least one selected measure of quality being a plurality of selected measures of quality, said plurality of selected measures of quality being determined in said determining at least one quality measure step.

5. The process of claim 3, wherein said at least one primary frequency is coupled in said coupling step to said microwave resonator and is calibrated in said calibrating step to determine a moisture content of the fibrous web.

6. The process of claim 5, wherein said at least one microwave resonator is calibrated to measure the moisture content in said fibrous web is capable of operating in a range of frequencies between 1 GHz and approximately 25 GHz.

7. The process of claim 6, wherein said range of frequencies is set to operate in a regime proximate to 2.4 GHz.

8. The process of claim 6, wherein said range of frequencies is set to operate in a regime proximate to 22 GHz.

9. The process of claim 5, wherein said at least one primary frequency is also coupled in said coupling step to said microwave resonator and is calibrated in said calibrating step to determine a basis weight of the fibrous web.

10. The process of claim 9, wherein said at least one primary frequency has a frequency value which is calibrated to measure the basis weight is in a regime where dielectric constants of all filler material in the fibrous web are substantially the same.

11. The process of claim 9, wherein said at least one primary frequency of said microwave resonator that is calibrated to measure the basis weight is operating in a range of 22 GHz up to approximately 100,000 GHz,

12. The process of claim 11, wherein said range is from 50 GHz up to approximately 500 GHz.

13. The process of claim 11, wherein said range is from 60 GHz up to approximately 300 GHz.

14. The process of claim 5, wherein said at least one primary frequency is also coupled in said coupling step to said microwave resonator and is calibrated in said calibrating step to measure at least one characteristic of a filler material that is contained in the fibrous web.

15. The process of claim 14, further comprising the step of selecting said primary frequencies so that measurements are conducted for both a content of intended filler ingredients of the fibrous web and the moisture content, and a basis weight for the fibrous web is determined through a combination of these selective measurements.

16. The process of claim 1, wherein said evaluating step directed at said resonance curve leads to a determination of a dielectric constant of the fibrous web, the dielectric constant leading to the determination of at least one measure of quality of the fibrous web in said determining step.

17. The process of claim 16, wherein said at least one microwave resonator is a plurality of microwave resonators, the measures of quality are conducted on the fibrous web as the fibrous web moves utilizing several of said microwave resonators that are stationary and are distributed across a width of the fibrous web.

18. The process of claim 17, wherein a majority of said stationary microwave resonators are engaged to measure at least one common measure of quality simultaneously.

19. The process of claim 16, wherein the measure of quality is conducted on a moving fibrous web using said at least one microwave resonator that traverses a width of the fibrous web.

20. A device to measure at least one qualitative measure of a moving fibrous web, the fibrous web being one of paper and cardboard, the device comprising:
at least one microwave resonator;
an apparatus to evaluate a resonance curve of waves that are emitted by said microwave resonator; said microwave resonator having been influenced by the fibrous web; and
means to determine measures of quality from results of the evaluation performed by said apparatus on the resonance curve.

21. The device of claim 20, wherein the device is configured to determine the measure of quality as determined by at least one of a position of the resonance along an axis of frequency, a form of the resonance curve and a width of the resonance curve.

22. The device of claim 21, further comprising an apparatus configured to couple a selected primary frequency into said microwave resonator which is calibrated to the measure of quality that is to be determined.

23. The device of claim 21, further comprising an apparatus configured to couple several selected primary frequencies into said microwave resonator, said microwave resonator being attuned to various measures of quality that are to be determined.

24. The device of claim 22, wherein the measure of quality is a moisture content of the fibrous web.

25. The device of claim 24, wherein said at least one microwave resonator which is measuring the moisture content in the fibrous web is capable of operating in a range of frequencies between 1 GHz to approximately 25 GHz

26. The device of claim 25, wherein said at least one microwave resonator is set to operate in a regime around 2.4 GHz

27. The device of claim 25, wherein said at least one microwave resonator is set to operate in a regime around 22 GHz.

28. The device of claim 23, wherein the measure of quality is a basis weight of the fibrous web.

29. The device of claim 28, wherein a frequency value of a selected primary frequency which is calibrated to measure the basis weight is in a regime where dielectric constants of all filler materials of the fibrous web are substantially the same.

30. The device of claim 28, wherein a selected primary frequency of said microwave resonator which is calibrated to measure the basis weight is operating in a range of 22 GHz to approximately 100,000 GHz.

31. The device of claim 30, wherein said range is 50 GHz to approximately 500 GHz.

32. The device of claim 31, wherein said range is 60 GHz to approximately 300 GHz.

33. The device of claim 20, wherein said at least one primary frequency is coupled to said at least one microwave resonator and the device is calibrated to measure at least one filler material that is contained in the fibrous web.

34. The device of claim 20, wherein the device is configured through selection of the primary frequencies to conduct selective measurements for determining a content of intended filler ingredients, a moisture content and a basis weight through a combination of these selective measurements.

35. The device of claim 34, wherein said at least one microwave resonator is a plurality of microwave resonators which are distributed across a width of the fibrous web.

36. The device of claim 34, wherein said at least one microwave resonator is configured to traverse across a width of the fibrous web.

37. The device of claim 20, wherein said at least one microwave resonator includes a first microwave resonator and a second microwave resonator, said first microwave resonator being used to determine a basis weight of the fibrous web, said second microwave resonator being used to determine a moisture content of the fibrous web.

38. The device of claim 20, wherein said at least one microwave resonator includes a planar microwave ring resonator.

39. The device of claim 38, wherein said microwave ring resonator has a size that is approximately the size of the wavelength of a primary frequency.

40. The device of claim 20, wherein said at least one microwave resonator includes an individual microwave resonator and a planar microwave ring resonator at least one of which is embedded in a ceramic, said ceramic being used in one of a press or a press nip of a papermaking machine.

41. The device of claim 20, wherein said at least one microwave resonators is employed to determine different measures of quality, the device being configured to quantify from these measures of quality a governing value that serves to control the manufacture of the fibrous web.
